(19) United States
(12) Patent Application Publication
(10) Pub. No.: US 2002/0191365 A1
(43) Pub. Date: Dec. 19, 2002

(54) Potted electrical components and methods therefor

(76) Inventors: Curtis J. Byler, Ft. Worth, TX (US); Carl R. Harrison, Decatur, TX (US)

Correspondence Address: CORNING CABLE SYSTEMS LLC, P O BOX 489, HICKORY, NC, 28603, US

(21) Appl. No.: 09/882,833

(22) Filed: Jun. 15, 2001

(51) Int. Cl. H05K 5/06

(52) U.S. Cl. 361/301.3

(57) ABSTRACT

A potted electrical component and a manufacturing method therefor including at least one electrical component at least partially encapsulated in a potting compound. A basket is at least partially disposed between an outer surface of the potting compound and the electrical component. The potted electrical component may include a plate. The plate may have no electrical components, at least one integral electrical component, at least one electrical component mounted to the plate, or any combination thereof. Additionally, the basket may be attached to an assembly.

### FIELD OF THE INVENTION

The present invention relates generally to potted electrical components and methods therefor.

### BACKGROUND OF THE INVENTION

Electrical components require protection from detrimental effects, for example, vibration and/or environmental effects. A known method for providing protection to electrical components is encapsulating them in a potting material. A conventional method of potting an electrical component requires placing the electrical components in a metal housing and pouring the potting compound into the metal housing. An example of a potted transformer is disclosed in U.S. Pat. No. 3,584,106. The transformer is positioned within a metal housing having an open top and encapsulated by a potting compound. A spacer member is positioned adjacent to the open top of the metal housing and is removed after the potting compound cures. The spacer member produces a void area between the cured potting compound and a portion of the metal housing. The void area allows the potting compound to expand when the transformer heats up during operation, thereby inhibiting buckling of the metal housing. Although this method of potting a transformer is designed to provide protection, the potting material can still expand and damage the metal housing.

An example of a housing for protecting a connector block encapsulated by a potting compound is disclosed in U.S. Pat. No. 4,827,502. The connector block is mounted in the housing with the terminals of the connector block facing the bottom of the housing. The potting compound is then poured into the housing, thereby encapsulating the terminals and connections of the connector block. The housing includes a hingedly attached cover having a sealing means for preventing environmental elements from reaching protector modules attached to the top of the connector block. Although this housing is designed to provide protection to the connector block, the assembly requires numerous parts that can be relatively expensive, and thus, increase manufacturing costs.

### SUMMARY OF THE INVENTION

The present invention is directed to a potted electrical component including at least one electrical component, a potting compound having the electrical component being at least partially encapsulated therein, and a basket, the basket being at least partially disposed between an outer surface of the potting compound and the electrical component.

The present invention is also directed to a potted electrical component including a potting compound having a protector block being at least partially encapsulated therein, the protector block having at least one electrical connection, a basket, the basket being at least partially disposed between an outer surface of the potting compound and the protector block, and at least one wire passing through the potting compound being electrically attached to the at least one electrical connection of the protector block.

The present invention also includes a method of manufacturing a potted electrical component including providing at least one electrical component and a basket, placing the at least one electrical component and the basket in a predetermined position relative to a potting mold, filling the potting mold with a potting compound, the at least one electrical component being encapsulated within the potting compound, and the basket being at least partially disposed between an outer surface of the potting compound and the electrical component, and ejecting the potted electrical component from the potting mold after the potting compound is cured.

The present invention is further directed to a potted electrical component including at least one electrical component, a potting compound having the electrical component being at least partially encapsulated therein, and a basket, the basket having at least a portion thereof encapsulated in the potting compound.

### BRIEF DESCRIPTION OF THE FIGS

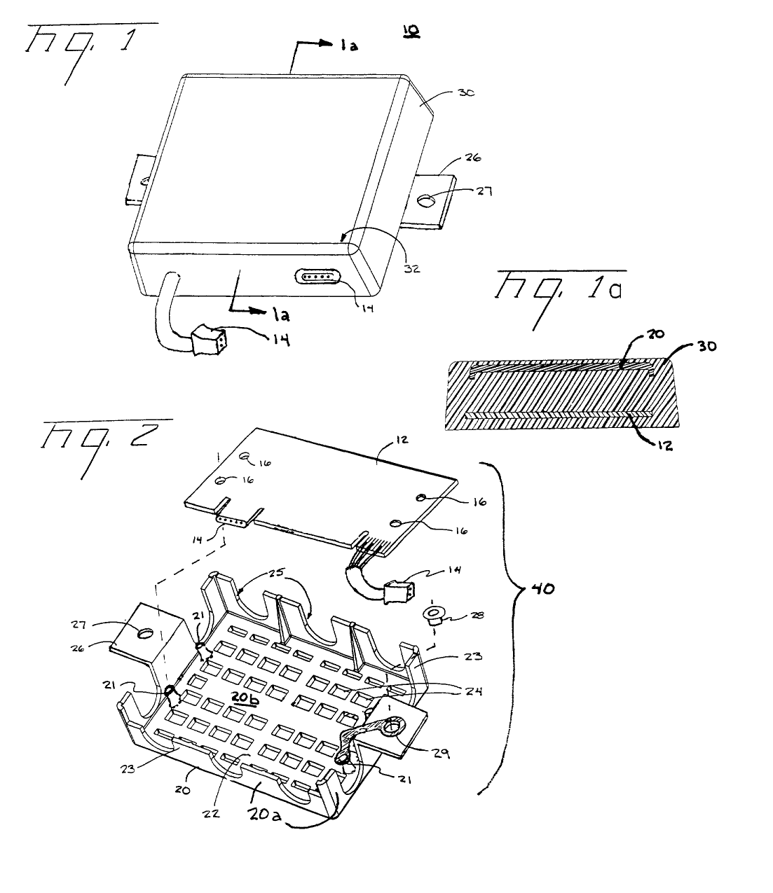

FIG. 1 is a perspective view of a potted electrical component in accordance with the present invention.

FIG. 1a is a sectional view of the potted electrical component of FIG. 1 taken along 1a-1a.

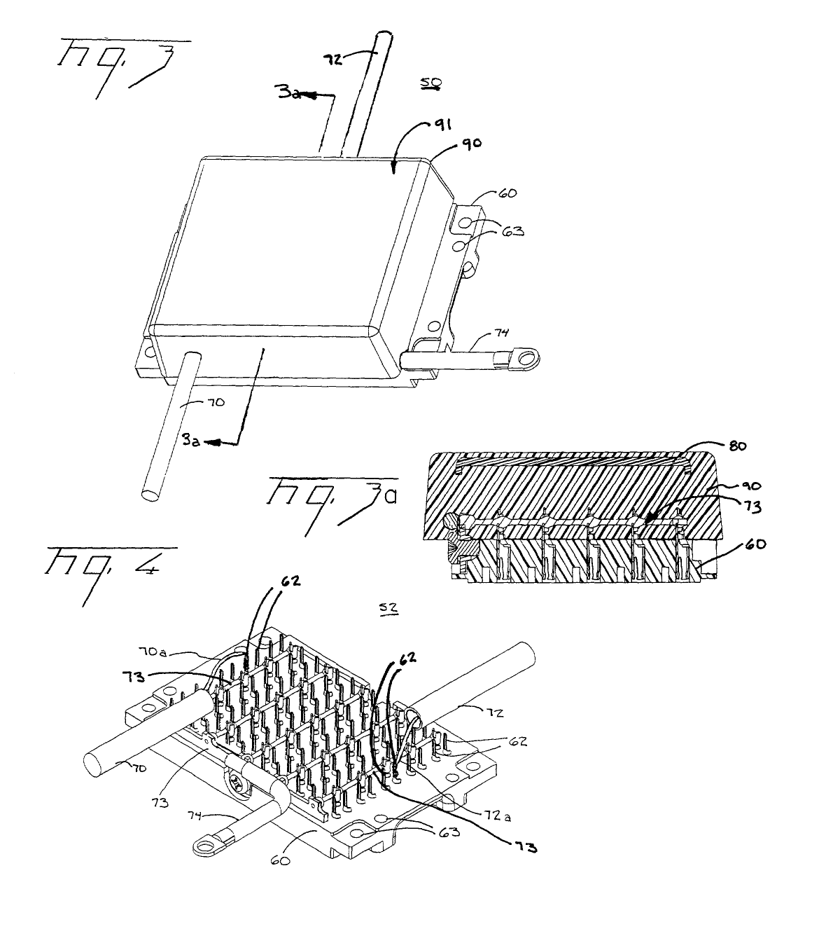

FIG. 2 is an exploded perspective view of a basket subassembly of the potted electrical component of FIG. 1 as viewed from the bottom.

FIG. 3 is a perspective view of another embodiment of a potted electrical component in accordance with the present invention.

FIG. 3a is a sectional view of the potted electrical component of FIG. 3 taken along 3a-3a.

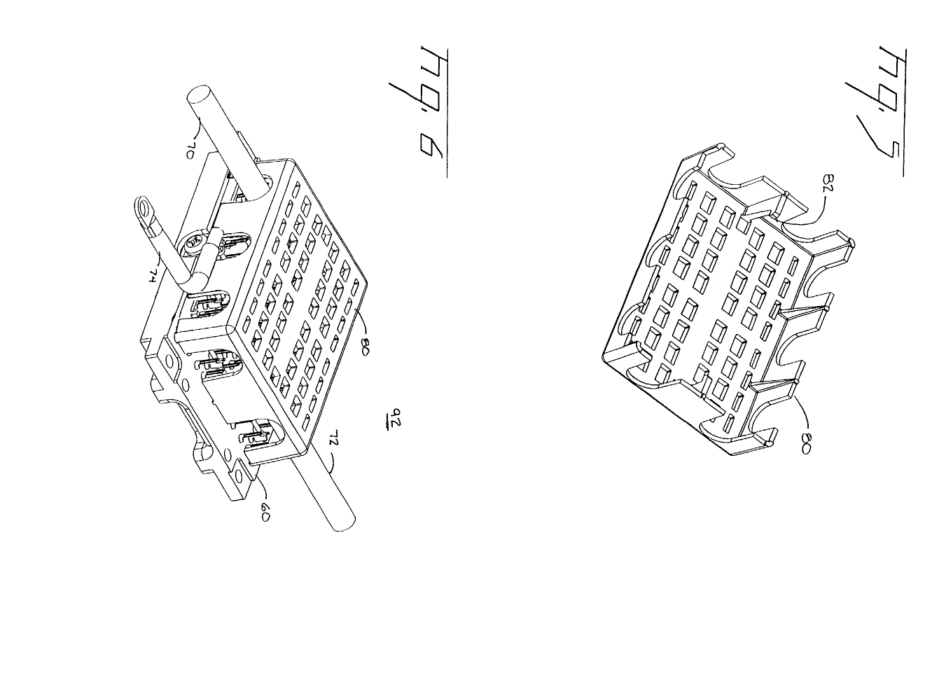

FIG. 4 is a perspective view of an electrical subassembly of a potted electrical component as viewed from the top.

FIG. 5 is a perspective view of an exemplary basket of a potted electrical component in accordance with the present invention.

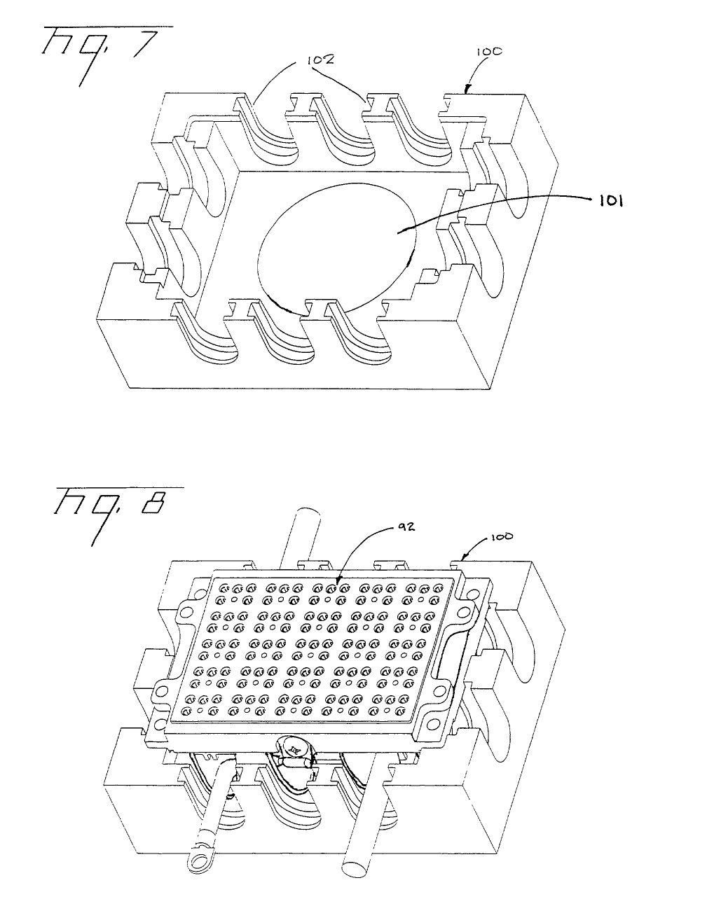

FIG. 6 is a perspective view of the electrical subassembly of FIG. 4 after at least one manufacturing step illustrating a basket subassembly.

FIG. 7 is a perspective view of an exemplary potting mold in accordance with the present invention.

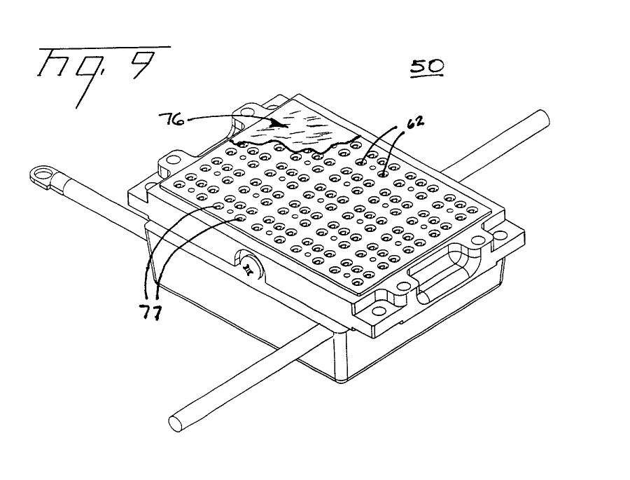

FIG. 8 is a perspective view of the basket subassembly of FIG. 6 placed in a predetermined position in the potting mold of FIG. 7.

FIG. 9 is a bottom perspective view of the potted electrical component of FIG. 3.

### DETAILED DESCRIPTION OF THE INVENTION

A potted electrical component 10 for an electrical component according to an embodiment of the present invention is depicted in FIG. 1. FIG. 2 illustrates an explanatory basket subassembly 40 of potted electrical component 10. Potted electrical component 10 includes at least one electrical component 12, a basket 20, and a potting compound 30. At least one electrical component 12 is at least partially disposed in potting compound 30. Basket 20 is at least partially disposed between an outer surface 32 of potting compound 30 and electrical component 12. Basket 20 can include tabs 26 for mounting potted electrical component 10 to, for example, a connector panel.

As shown in FIG. 2, electrical component 12 includes a printed circuit board that is attached to basket 20, but electrical component 12 can be attached to, for example, a plate. Moreover, electrical component 12 may include any type of electrical component, for example, cables, capacitors, diodes, fuses, microprocessors, protector blocks, resistors, terminal blocks, thyristors, transistors, transformers and/or wires. In one embodiment, electrical component 12 is supported and/or attached to basket 20 by standoffs 21 of a predetermined height. However, electrical component 12 may supported by, or attached to basket 20 in other ways, for example, adhesives, friction fitted, or fasteners. Electrical component 12 may include any known connector 14 for completing an electrical circuit. For example, a pigtail connector or a pin connector may be used as an input, output, or both. Connector 14 may be entirely encapsulated in potting compound 30 or partially encapsulated in potting compound 30.

Basket 20 is a generally rectangular box-like structure generally having a bottom 22 and sidewalls 23. However, basket 20 may be of any suitable shape configured to receive at least a portion of electrical component 12. Basket 20 preferably is made of a dielectric material, for example, polyethylene; however basket 20 may also be made of other dielectric materials, a conductive material, a semi-conductive material, or combinations thereof. Basket 20 provides containment of electrical component 12. Illustratively, without basket 20, wires may migrate to outer surface 32 of potting compound 30 during manufacturing, thereby inhibiting potting compound 30 from covering the wires, generally an undesired effect. However, basket 20 can inhibit wires from migrating to outer surface 32 of potting compound 30 during manufacturing, thereby encapsulating the wires in potting compound 30. Moreover, basket 20 may provide additional protection to electrical component 12 and/or potted electrical component 10, for example, potting compound 30 may expand without damaging potted electrical component 30.

Basket 20 typically includes at least one aperture 24 generally located on bottom 22. Aperture 24 is suitable for permitting potting compound 30 to flow through and/or around basket 20, thereby at least partially disposing basket 20 in potting compound 30. Sidewalls 23 may include a plurality of cutouts 25 permitting potting compound 30 to flow around sidewalls 23 of basket 20 and/or routing connector 14 to electrical component 12, however sidewalls 23 may be generally continuous. Cutouts 25 can be any predetermined shape or size. Basket 20 may include more cutouts 25 than connectors 14 routed to electrical component 12, thereby allowing for a variety of connector 14 configurations. In another embodiment, basket 20 has no apertures 24, but includes more cutouts 25 than connectors 14 routed to electrical component 12 allowing potting compound 30 to flow through cutouts 25.

Basket 20 of another embodiment includes at least one mounting tab 26. Mounting tab 26 is typically not covered with potting compound 30 so that an aperture 27 may be used for mounting potted electrical component 10. Additionally, a grounding strap 29 may be routed to aperture 27 providing a ground connection for electrical element 12. However, other grounding configurations may be employed as well. For example, a conductive ferrule 28 may be used to attach a first end of grounding strap 29 adjacent to aperture 27 so that when potted electrical component 10 is mounted, for instance, to a firewall ferrule 28 makes electrical contact to a ground point on the firewall. A second end of grounding strap 29 may be electrically attached to electrical component 12, for example, the second end may be routed to one standoff 21 contacting a ground point of electrical component 12 or may be soldered to electrical component 12.

Another embodiment includes a plate for mounting potted electrical component 10, instead of tabs 26 of basket 20. Plate would have apertures for mounting potted electrical component 10. Basket 20 having electrical component 12 then attaches to the plate by any suitable manner and would be potted as described herein.

Potting compound 30 is preferably a two-component compound, more specifically, Polycin® 3526 and Vorite® 3022 available from CasChem, Inc. of Bayonne, N.J. However, other suitable potting compounds may be used. Potting compound 30 typically forms at least a portion of an outer surface 32 of potted electrical component 10. In one embodiment, potting compound 30 preferably generally contacts a portion of an inner surface 20b of basket 20. More preferably, potting compound 30 generally covers an outer surface 20a of basket 20, and most preferably, potting compound generally covers sidewall 23 by about one quarter of an inch and covers bottom 22 by about one eighth of an inch. (See FIGS. 1a and 3a.) However potting compound 30 may be generally flush with basket 20 or cover basket 20 by any thickness of potting compound 30.

Potted electrical component 50, another embodiment of the present invention, is illustrated in FIG. 3. As described in conjunction with the embodiments of FIG. 1, potted electrical component 50 may include an electrical subassembly 52 as depicted in FIG. 4. Electrical subassembly 52 includes a plate 60 having a protector module that may be used, for example, to protect subscriber telephones and/or indoor wiring from overcurrent and/or overvoltage conditions. Plate 60 may also be used for mounting potted electrical component 50. Plate 60 may also include other configurations, for example, plate 60 may have: no electrical components; at least one integral electrical component; at least one electrical component mounted thereto; or any combination thereof. In one embodiment, plate 60 may include a plurality of pins 62 on a generally planar surface of plate 60, but any suitable electrical connector may be used. At least one wire 70a of a first end of a first cable 70 is connected to at least one pin 62 of plate 60. Likewise at least one wire 72a of a first end of a second cable 72 is connected to at least one pin 62 of plate 60. Cable 70 may be an incoming telephone communication cable and cable 72 may be an outgoing subscriber telephone cable. Plate 60 may include a ground bus bar 73 having a grounding cable 74 electrically connected thereto. Plate 60 may also include at least one aperture 63 on a portion of plate 60 that is generally outside potting compound 90 for mounting potted electrical component 50. In one embodiment, (See FIG. 9.) a layer 76 may be used to further seal the electrical connections that are not encapsulated by potting compound 90, for example, sockets 77 on a bottom of plate 60. Layer 76 preferably is a two-component silicone gel, more specifically, Amicon LS-2334-31A and Amicon LS-2334-31B available from Emerson & Cuming Specialty Polymers, of Billerica, Mass. However, other suitable sealing materials may be used.

FIG. 5 illustrates basket 80, which is similar to basket 20. Basket 80 includes at least one finger 82 for attaching basket 80 to a single member or an assembly of more than one part. More particularly, two fingers 82 attach to electrical subassembly 52, more specifically, two fingers 82 attach to opposite sides of bus bar 73 of electrical subassembly 52. However, any suitable means for attaching basket 80 to a single member or an assembly may be used, for example, adhesives, bolts, friction fitting, latches, screws, snap fitting and/or threaded studs with nuts. For example, fingers 82 may snap into an aperture of plate 60 or screws may enter an aperture of plate 60 from the bottom threadly engaging basket 80.

The manufacture of potted electrical components according to the present invention may be accomplished by operation of the following exemplary process describing the manufacture of potted electrical component 50 of FIG. 3.

FIG. 4 illustrates plate 60 having electrical connection points, for example, pins 62, provided for electrically attaching wires from first cable 70 and wires from second cable 72. Predetermined electrical connections can be made between pins 62 and wires of cables 70,72, as is well known in the art. Grounding cable 74 may be attached to ground bus bar 73 by any suitable means, for example, a threaded bolt. Thereafter, basket 80 is attached to electrical subassembly 52, which defines basket subassembly 92. (See FIG. 6.) However, basket subassembly 92 may be defined with fewer components, for example, electrical component 12 and basket 20.

As depicted in FIG. 7, a mold 100 is provided for forming potting compound 90 around basket subassembly 92. Mold 100 can be filled through an aperture (not illustrated) as is known to one of ordinary skill in the art. Mold 100 includes an ejector plug 101 (installed) that may be removed to permit ejecting of potted electrical component 50 after being suitably cured. Mold 100 may also include a plurality of mold cutouts 102 at predetermined locations. Mold cutouts 102 generally correspond with basket cutouts 25 and may be any predetermined size or shape allowing for various configurations. Mold cutouts 102 permit cables 70, 72 and 74 to be routed to and/or from plate 60. Where a cable does not enter or exit mold 100, a blank grommet (not illustrated) may be positioned in a groove of mold cutout 102 for inhibiting potting compound from flowing out of the mold cutout area during manufacturing. Where a cable runs into mold 100, a grommet having an opening may be used, thereby permitting the cable to enter or exit the mold through the grommet while inhibiting potting compound from flowing out between the cable and the mold cutout 102. Additionally, a grommet may include an aperture for filling mold 100. However, mold 100 does not require grommets, a mold with generally continuous sides and having a filling aperture located on the mold may be used.

Basket subassembly 92 is prepared for pouring potting compound 90 by placing basket subassembly 92 into mold 100 along with any grommets. FIG. 8 depicts basket subassembly 92 in a predetermined position relative to mold 100. Potting compound 90 is then poured into the filling aperture, filling mold 100. When potting compound 90 is suitably cured, ejector plug 101 is removed from mold 100 and potted electrical component 50 is ejected from mold 100. Potting compound 90 forms at least a portion of the outer surface 91 of potted electrical component 50. As illustrated in FIG. 9, layer 76 may be applied to sockets 77 thereby sealing sockets 77 and/or pins 62 from detrimental elements.

Many modifications and other embodiments of the present invention, within the scope of the appended claims, will become apparent to a skilled artisan. For example, potted electrical components may be formed in gangs of more than one by injection molding a plurality of baskets together and/or having a gang mold and separating the cured potted electrical components. The present invention could also include a basket without apertures or cutouts while still having the basket disposed between an outer surface of the compound and the electrical component. Therefore, it is to be understood that the invention is not to be limited to the specific embodiments disclosed and that modifications and other embodiments may be made within the scope of the appended claims. Although specific terms are employed herein, they are used in a generic and descriptive sense only and not for purposes of limitation. The invention has been described with reference to potted electrical components of a printed circuit board and a protector block but the inventive concepts of the present invention are applicable to other electrical components as well.

That which is claimed:

1. A potted electrical component comprising:
at least one electrical component;
a potting compound having said electrical component being at least partially encapsulated therein; and
a basket, said basket being at least partially disposed between an outer surface of the potting compound and the at least one electrical component.

2. The potted electrical component according to claim 1, wherein said basket includes at least one aperture.

3. The potted electrical component according to claim 1, further comprising a plate attached to the basket and adjacent to said potting compound.

4. The potted electrical component according to claim 3, said plate being a portion of a protector block.

5. The potted electrical component according to claim 1, said basket being attachable to an electrical subassembly.

6. The potted electrical component according to claim 1, further comprising a grounding strap to ground said at least one electrical component.

7. The potted electrical component according to claim 1, further comprising a layer to seal a portion of said at least one electrical component not encapsulated by said potting compound.

8. The potted electrical component according to claim 1, further comprising an electrical connector being electrically attached to said at least one electrical component, said connector being at least partially disposed between said basket and said electrical component.

9. A potted electrical component comprising:
a potting compound having a protector block being at least partially encapsulated therein, said protector block having at least one electrical connection;
a basket, said basket being at least partially disposed between an outer surface of said potting compound and said protector block; and
at least one wire passing through said potting compound being electrically attached to said at least one electrical connection of said protector block.

10. The potted electrical component according to claim 9, said basket includes at least one aperture.

11. The potted electrical component according to claim 9, said basket being attachable to an electrical subassembly.

12. The potted electrical component according to claim 9, further comprising a grounding strap to ground said protector block.

13. The potted electrical component according to claim 9, further comprising a layer to seal a portion of said at least one electrical component not encapsulated by said potting compound.

14. A method of manufacturing a potted electrical component comprising:
providing at least one electrical component and a basket;
placing said at least one electrical component and said basket in a predetermined position relative to a potting mold;
filling said potting mold with a potting compound, said at least one electrical component being encapsulated within said potting compound, and said basket being at least partially disposed between an outer surface of said potting compound and the electrical component; and
ejecting said potted electrical component from said potting mold after the potting compound is cured.

15. The method of manufacturing the potted electrical component according to claim 14, said step of providing said basket further including providing said basket having at least one aperture.

16. The method of manufacturing the potted electrical component according to claim 14, further comprising the step of providing a plate and placing said plate in a predetermined position relative to said potting mold.

17. The method of manufacturing the potted electrical component according to claim 16, said step of providing a plate further including providing said plate that is a portion of a electrical subassembly.

18. The method of manufacturing the potted electrical component according to claim 14, further comprising the step of attaching said basket to an assembly of more than one part forming a basket subassembly after the providing step.

19. The method of manufacturing the potted electrical component according to claim 14, further comprising the step of making an electrical connection between at least one wire and said at least one electrical component before the placing step.

20. A potted electrical component comprising:
at least one electrical component;
a potting compound having said electrical component being at least partially encapsulated therein; and
a basket, said basket having at least a portion thereof encapsulated in the potting compound.
